(19) United States
(12) Patent Application Publication
(10) Pub. No.: US 2025/0301700 A1
(43) Pub. Date: Sep. 25, 2025

(54) SEMICONDUCTOR DEVICE AND METHOD FOR FORMING THE SAME

(71) Applicant: Hon Young Semiconductor Corporation, Hsinchu City (TW)

(72) Inventors: Iram SIDDIQUI, Hsinchu City (TW); Kuang-Hao CHIANG, Hsinchu City (TW); Yan-Ru CHEN, Hsinchu City (TW)

(21) Appl. No.: 18/656,616

(22) Filed: May 7, 2024

(30) Foreign Application Priority Data
Mar. 20, 2024 (TW) 113110392

(51) Int. Cl. H01L 29/78; H01L 21/265; H01L 29/66

(52) U.S. Cl. CPC H10D 30/668; H01L 21/26513; H10D 30/0297

(57) ABSTRACT

A semiconductor device includes an epitaxial layer, a gate structure, a well, and a source electrode. The epitaxial layer has a first conductive type. The gate structure is disposed in the epitaxial layer and has a curved surface protruding into the epitaxial layer. A breadth depth ratio of the gate structure is less than or equal to 1. The well is disposed in the epitaxial layer. The well has a second conductive type different from the first conductive type. The well extends into the epitaxial layer along the curved surface of the gate structure. The well is in contact with the curved surface. The source electrode is disposed above the epitaxial layer and is electrically connected to the well.

### CROSS-REFERENCE TO RELATED APPLICATION

This application claims priority to Taiwan Application Serial Number 113110392, filed Mar. 20, 2024, which is herein incorporated by reference in its entirety.

### BACKGROUND

### Field of Disclosure

The present disclosure relates to a semiconductor device and a method for forming the same.

### Description of Related Art

Metal oxide semiconductor field effect transistors (MOSFET) are widely used in electronic devices due to their advantages such as fast switching speed, ideal high-frequency characteristics, high input impedance, and low driving power.

Generally speaking, the on-state resistance of MOSFETs is an important parameter that affects their power consumption. MOSFETs with trench gate structures have higher channel density. Such characteristic can help reduce the on-state resistance and scale down the component size, therefore increasing the component density of the chip and reducing costs. However, the gate structures of trench gate power MOSFETs may induce large electric field concentrations, which may reduce the breakdown voltage of the components and thus cause reliability problems.

Accordingly, how to provide a semiconductor device and a method for forming the semiconductor device to solve the aforementioned problems becomes an important issue to be solved by those in the industry.

### SUMMARY

An aspect of the disclosure is to provide a semiconductor device and a method for forming the semiconductor device that may efficiently solve the aforementioned problems.

According to some embodiments of the present disclosure, a semiconductor device includes an epitaxial layer, a gate structure, a well, and a source electrode. The epitaxial layer has a first conductive type. The gate structure is disposed in the epitaxial layer and has a curved surface protruding into the epitaxial layer. A breadth depth ratio of the gate structure is less than or equal to 1. The well is disposed in the epitaxial layer. The well has a second conductive type different from the first conductive type. The well extends into the epitaxial layer along the curved surface of the gate structure. The well is in contact with the curved surface. The source electrode is disposed above the epitaxial layer and is electrically connected to the well.

According to some other embodiments of the present disclosure, a method of forming a semiconductor device includes forming an epitaxial layer on a substrate. The epitaxial layer has a first conductive type. The method further includes performing a first implantation process to form a well in the epitaxial layer and having a second conductive type different from the first conductive type. The method further includes performing a second implantation process to form a source region in the epitaxial layer and having the first conductive type.

The source region is disposed on the well. The method further includes removing a portion of the epitaxial layer, the well, and the source region to form a curved groove that is concave inward the epitaxial layer and exposes the well. The method further includes forming a gate structure in the curved groove. The gate structure has a curved surface contacting the curved groove. A breadth depth ratio of the gate structure is less than or equal to 1.

Accordingly, in the semiconductor device and the method of forming the semiconductor device of some embodiments of the present disclosure, by forming a gate structure with a curved surface, the gate structure does not have corner points. Therefore, the accumulation of electric fields that commonly occurs near the corner points may be prevented. To be more specific, by forming a curved groove that is concave inward the epitaxial layer and then forming a gate structure to fill the curved groove, the gate structure has a curved surface. Thus, electric field accumulation may be prevented, thereby increasing the breakdown voltage of the semiconductor device and reducing the on-state resistance.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial cross-sectional view of a semiconductor device according to some embodiments of the present disclosure;

FIG. 2 to FIG. 4 are partial cross-sectional views of intermediate stages of a method for forming a semiconductor device according to some embodiments of the present disclosure; and

FIG. 5 to FIG. 7 are partial cross-sectional views of a semiconductor device according to some other embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

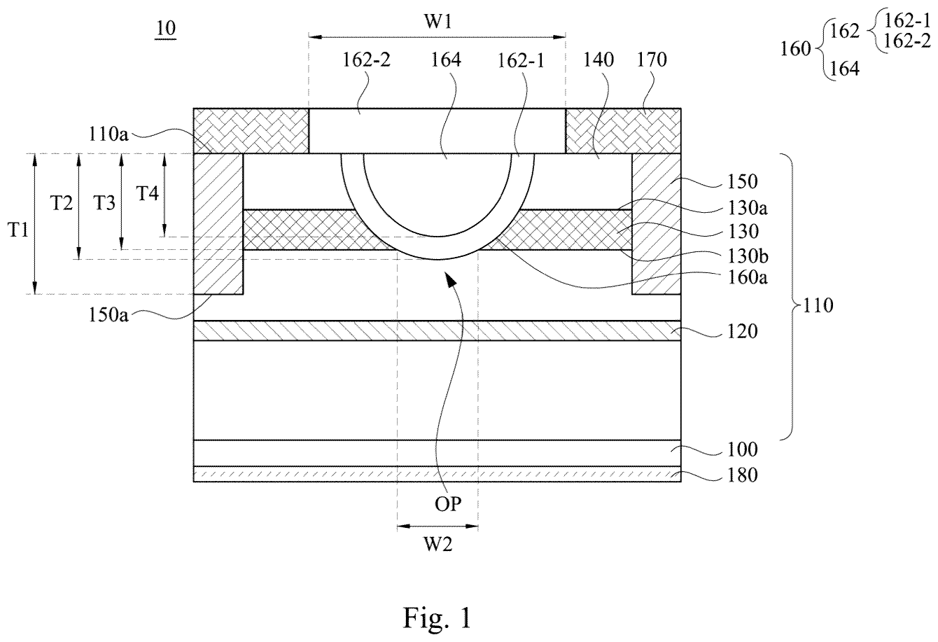

Reference is made to FIG. 1. FIG. 1 is a partial cross-sectional view of a semiconductor device 10 according to some embodiments of the present disclosure. As shown in FIG. 1, the semiconductor device 10 includes a substrate 100, an epitaxial layer 110, a current spreading layer 120, a well 130, a source region 140, a heavily doped region 150, a gate structure 160, a source electrode 170, and a drain electrode 180.

As shown in FIG. 1, the epitaxial layer 110 is disposed on the substrate 100. The current spreading layer 120 is disposed in the epitaxial layer 110. The well 130, the source region 140, and the heavily doped region 150 are disposed in the epitaxial layer 110 and above the current spreading layer 120. The source region 140 is disposed on the well 130 and is in contact with a top surface 130a of the well 130. The heavily doped region 150 is disposed on a side of the well 130 and the source region 140 that is away from the gate structure 160. In other words, the well 130 and the source region 140 are disposed between the gate structure 160 and the heavily doped region 150. The gate structure 160 includes a gate oxide layer 162 and a gate electrode 164. The gate oxide layer 162 and the gate electrode 164 are disposed in the epitaxial layer 110 and at least partially disposed on the well 130 and the source region 140.

In some embodiments, the source electrode 170 is formed on a top surface 110a of the epitaxial layer 110 and above the heavily doped region 150. In other words, the heavily doped region 150 is disposed between the epitaxial layer 110 and the source electrode 170. The source electrode 170 is electrically connected to the well 130. The drain electrode 180 is formed below the substrate 100. The source electrode 170 and the drain electrode 180 may include conductive metal.

In some embodiments, the substrate 100, the epitaxial layer 110, the current spreading layer 120, and the source region 140 have the first conductive type. For example, the substrate 100, the epitaxial layer 110, the current spreading layer 120, and the source region 140 are n-type semiconductor layers. In some embodiments, a doping concentration of the epitaxial layer 110 is greater than a doping concentration of the current spreading layer 120. In some embodiments, a doping concentration of the source region 140 is greater than the doping concentration of the epitaxial layer 110. For example, a doping concentration of the substrate 100 is between about 10¹⁴ #/cm³ and about 1018 #/cm³. The doping concentration of the epitaxial layer 110 is between about 10¹⁵ #/cm³ and about 5×10¹⁶ #/cm³. The doping concentration of the current spreading layer 120 is between about 10¹¹ #/cm³ and about 10¹³ #/cm³. The doping concentration of the source region 140 is between about 10¹⁹ #/cm³ and about 10²¹ #/cm³. The epitaxial layer 110 may be formed as a drift region of the semiconductor device 10.

In some embodiments, the well 130 and the heavily doped region 150 have a second conductive type that is different from the first conductive type. For example, the well 130 and the heavily doped region 150 are p-type semiconductor layers. In some embodiments, a doping concentration of the heavily doped region 150 is greater than a doping concentration of the well 130. The well 130 is also called a lightly doped region. For example, the doping concentration of the well 130 is between about 10¹¹ #/cm³ and about 10¹⁴ #/cm³. The doping concentration of the heavily doped region 150 is between about 10¹⁹ #/cm³ and about 10²¹ #/cm³.

As aforementioned, the gate structure 160 includes a gate oxide layer 162 and a gate electrode 164. In some embodiments, the gate oxide layer 162 may include, for example, silicon dioxide. In some embodiments, the gate oxide layer 162 may include a first oxide layer 162-1 and a second oxide layer 162-2. The gate electrode 164 may include a polysilicon gate or a conductive metal.

As shown in FIG. 1, taking the top surface 110a of the epitaxial layer 110 as a reference, a bottom surface 150a of the heavily doped region 150 has a depth T1. The lowest point of the gate oxide layer 162 of the gate structure 160 has a depth T2. A bottom surface 130b of the well 130 has a depth T3. The lowest point of the gate electrode 164 of the gate structure 160 has a depth T4 (also referred to as the maximum depth of the gate electrode 164). As shown in FIG. 1, in some embodiments, the depth T1 is greater than the depth T3 to restrict the electric field. In some embodiments, the depth T2 is less than the depth T1 and greater than the depth T3. In some embodiments, the depth T4 is less than the depth T3.

In order to improve the reliability of the semiconductor device, in some embodiments of the present disclosure, the gate structure 160 is provided with a smoothly curved surface to prevent the electric field of the gate structure 160 from accumulating around corner points, thereby increasing the breakdown voltage and reducing the on-state resistance. Therefore, as shown in FIG. 1, the gate structure 160 has a curved surface 160a protruding into the epitaxial layer 110. Hence, the depth T2 may be referred to as the maximum depth of the curved surface 160a of the gate structure 160 relative to the top surface 110a. In some embodiments, the curved surface 160a extends upward and is connected to the top surface 110a of the epitaxial layer 110, but the present disclosure is not limited thereto. In some embodiments, the curved surface 160a may be formed with a plurality of arched surfaces with various radii of curvature, but the present disclosure is not limited thereto. In some embodiments, a radius of curvature of the curved surface 160a is greater than the depth T4 of the lowest point of the gate electrode 164 of the gate structure 160 relative to the top surface 110a.

As shown in FIG. 1, the well 130 extends toward the epitaxial layer 110 along the curved surface 160a and is in contact with the curved surface 160a. It should be noted that the well 130 does not extend to the lowest point of the curved surface 160a relative to the substrate 100. In other words, the well 130 has an opening OP, and the gate structure 160 is in contact with the epitaxial layer 110 through the opening OP. The opening OP of the well 130 may be formed as a channel region of the semiconductor device 10. As shown in FIG. 1, the maximum width of the gate oxide layer 162 of the gate structure 160 is the width W1, and the opening OP has the width W2. In some embodiments, the width W2 is less than 80% of the width W1. As such, the breakdown voltage may increase. In some embodiments, the lower the ratio between the width and the depth of the gate structure 160 (i.e., the breadth depth ratio), the lower the cell pitch and the on-resistance. For example, the breadth depth ratio may be between about 0.1 and about 1.

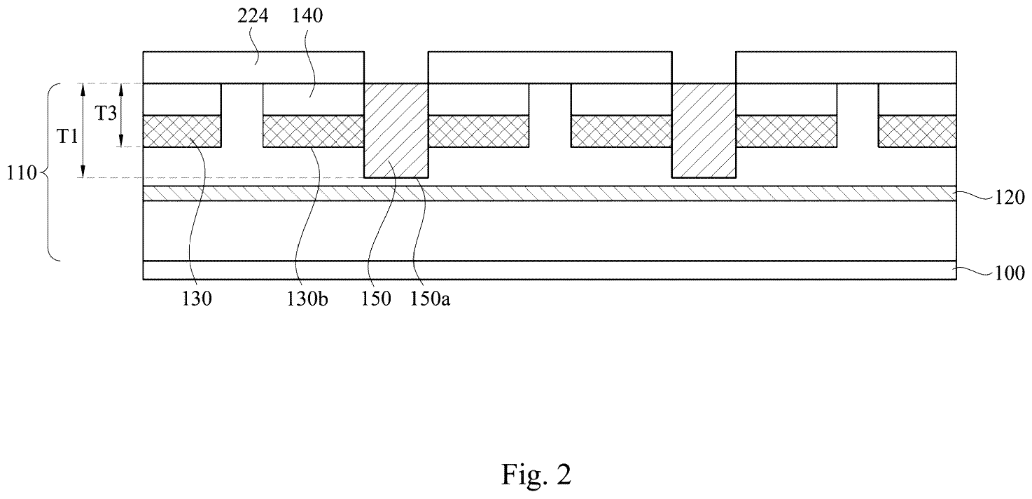

Reference is made to FIG. 2 to FIG. 4. FIG. 2 to FIG. 4 are partial cross-sectional views of intermediate stages of a method of forming the semiconductor device 10 according to some embodiments of the present disclosure. It should be noted that the partial cross-sectional views of the intermediate stages of the method illustrate a plurality of semiconductor devices 10 that are periodically arranged and connected.

First, reference is made to FIG. 2. As shown in FIG. 2, the epitaxial layer 110 is formed on the substrate 100. Next, a first implantation process (e.g., ion implantation) is performed to form the current spreading layer 120 in the epitaxial layer 110. The current spreading layer 120 is configured to reduce the on-state resistance of the semiconductor device 10. Then, a second implantation process is performed to form the well 130 in the epitaxial layer 110.

Then, a third implantation process is performed to form the source region 140 in the epitaxial layer 110 and on the well 130.

Later, a fourth implantation process is performed through a mask 224 (referring to FIG. 2) to form the heavily doped region 150 in the epitaxial layer 110 and adjacent to the well 130 and the source region 140. As aforementioned, the doping concentration of the heavily doped region 150 is greater than the doping concentration of the well 130. In some embodiments, as shown in FIG. 2, the depth T1 of the bottom surface 150a of the heavily doped region 150 is greater than the depth T3 of the bottom surface 130b of the well 130.

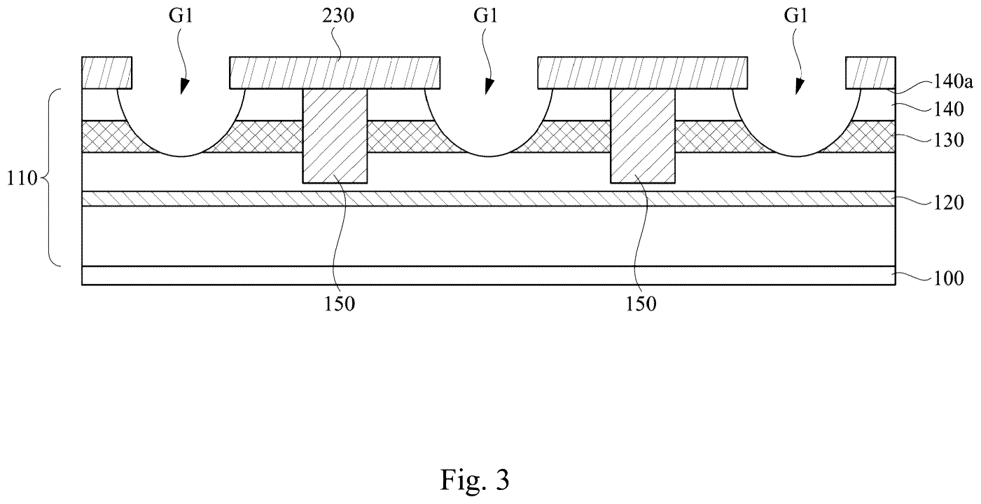

Reference is made to FIG. 3. Next, a portion of the epitaxial layer 110, the well 130, and the source region 140 is removed to form a plurality of grooves G1 to expose the well 130. For example, as shown in FIG. 3, the curved groove G1 is formed by etching through a hard mask 230. In some embodiments, the hard mask 230 includes silicon oxide (SiO₂). In some embodiments, the groove G1 further exposes the epitaxial layer 110.

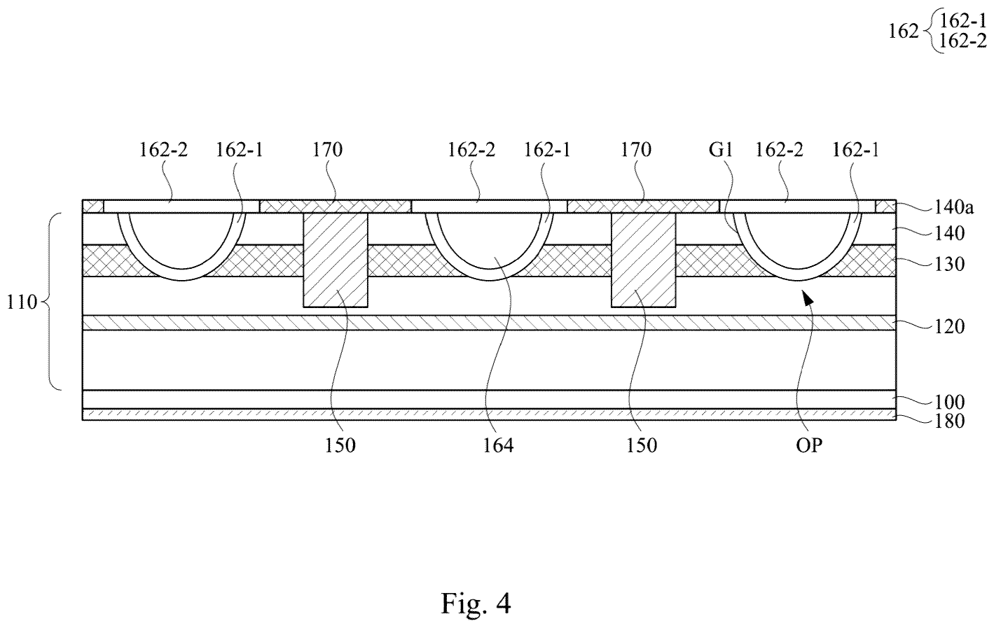

Reference is made to FIG. 4. Next, the hard mask 230 is removed and the gate structure is formed in the curved groove G1. As aforementioned, in some embodiments, the gate structure includes the gate oxide layer and the gate electrode. In some embodiments, the gate oxide layer is formed in two steps. For example, the first oxide layer 162-1 is firstly conformally deposited in the curved groove G1 and on the top surface of the source region 140 and the heavily doped region 150. In some embodiments, since the curved groove G1 further exposes the epitaxial layer 110, the first oxide layer 162-1 formed in the curved groove G1 is in contact with the epitaxial layer 110. In other words, the well 130 has an opening OP, and the epitaxial layer 110 is in contact with the first oxide layer 162-1 through the opening OP, as shown in FIG. 4. Next, the gate electrode 164 is deposited to further fill the curved groove G1 and completely cover the first oxide layer 162-1.

Then, a planarization process is performed to the formed first oxide layer 162-1 and the gate electrode 164, for example, by chemical mechanical polishing (CMP) to remove portions of the first oxide layer 162-1 and the gate electrode 164 that are higher than the top surface 140a of the source region 140, so as to expose the top surface 140a and make the first oxide layer 162-1 and the gate electrode 164 level with the top surface 140a.

Next, a second oxide layer 162-2 is deposited to cover the source region 140, the first oxide layer 162-1, and the gate electrode 164, so that the gate electrode 164 is surrounded by the first oxide layer 162-1 and the second oxide layer 162-2.

Then, a portion of the second oxide layer 162-2 is removed to form a plurality of trenches exposing the top surfaces of the source region 140 and the heavily doped region 150 and dividing the second oxide layer 162-2 into a plurality of separate portions. The formed first oxide layer 162-1 and the second oxide layer 162-2 are collectively referred to as the gate oxide layer 162. The gate oxide layer 162 and the gate electrode 164 are collectively referred to as the gate structure 160. The gate structure 160 fills the curved groove G1 (referring to FIG. 3) and is in contact with the well 130 and the source region 140 through the curved groove G1.

As a result, the gate structure 160 has a curved surface 160a that is concave inward the epitaxial layer 110. The curved surface 160a is in contact with the curved groove G1 and extends upward to be connected to the top surface of the epitaxial layer 110 (referring to the top surface 110a in FIG. 1). Therefore, the gate structure 160 does not have corner points, thereby preventing electric field accumulation that commonly occurs near corner points.

Finally, as shown in FIG. 4, the source electrode 170 is formed to fill the trenches exposing the source region 140 and the heavily doped region 150. At the same time, the drain electrode 180 is formed below the substrate 100. The formed semiconductor device structure is a vertical MOSFET with a trench gate structure, as shown in the semiconductor device 10 in FIG. 1.

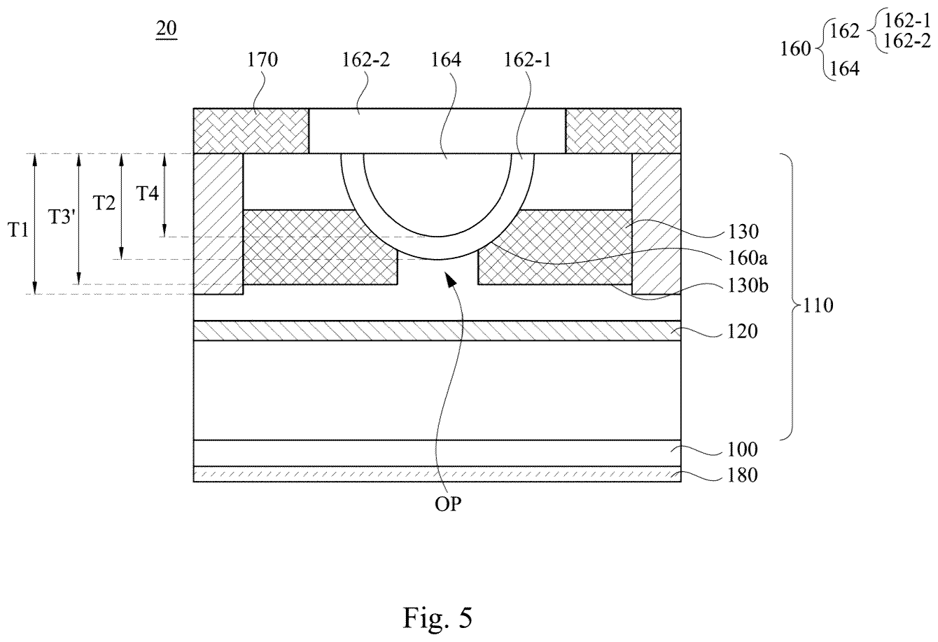

Reference is made to FIG. 5 to FIG. 7. FIG. 5 to FIG. 7 are partial cross-sectional views of a semiconductor device 20, a semiconductor device 30, and a semiconductor device 40 according to some other embodiments of the present disclosure. As shown in FIG. 5, the difference between the semiconductor device 20 and the semiconductor device 10 is that the depth T3′ of the bottom surface 130b of the well 130 of the semiconductor device 20 is greater than the depth T2 of the lowest point of the gate oxide layer 162 of the gate structure 160. It should be noted that the depth T1 of the bottom surface 150a of the heavily doped region 150 is still greater than the depth T3′.

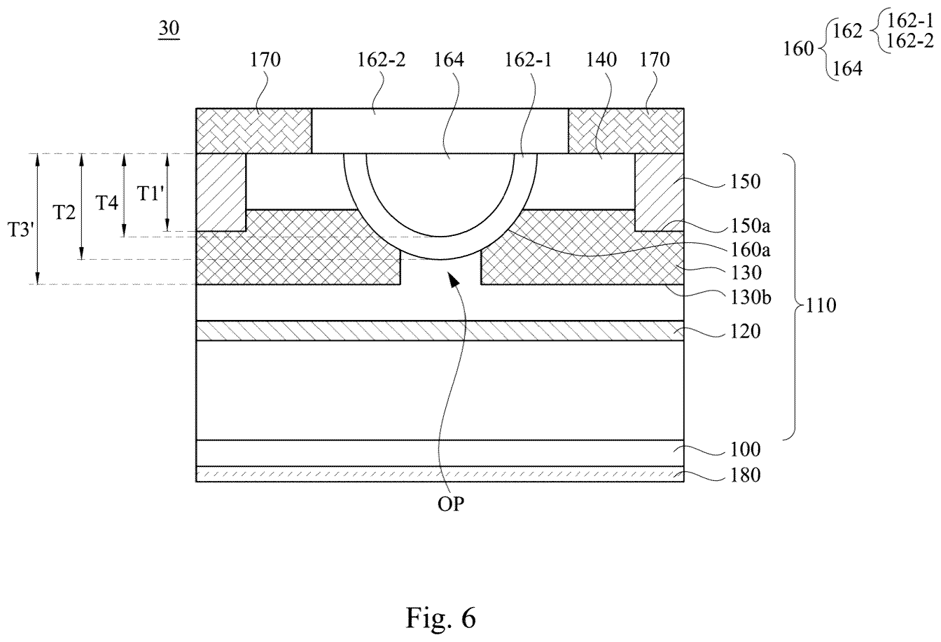

As shown in FIG. 6, the difference between the semiconductor device 30 and the semiconductor device 20 is that the depth T1′ of the bottom surface 150a of the heavily doped region 150 of the semiconductor device 30 is less than the depth T3′.

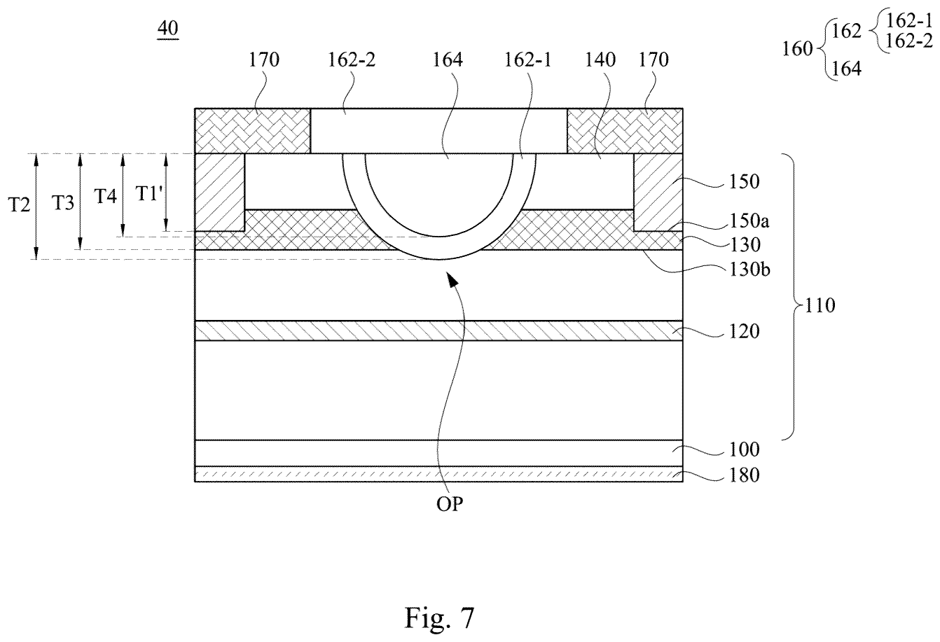

As shown in FIG. 7, the difference between the semiconductor device 40 and the semiconductor device 10 is that the depth T1′ of the bottom surface 150a of the heavily doped region 150 of the semiconductor device 40 is less than the depth T3′ of the well 130.

According to the foregoing recitations of the embodiments of the disclosure, it may be seen that in the semiconductor device and the method of forming the semiconductor device of some embodiments of the present disclosure, by forming a gate structure with a curved surface, the gate structure does not have corner points. Therefore, the accumulation of electric fields that commonly occurs near the corner points may be prevented. To be more specific, by forming a curved groove that is concave inward the epitaxial layer and then forming a gate structure to fill the curved groove, the gate structure has a curved surface. Thus, electric field accumulation may be prevented, thereby increasing the breakdown voltage of the semiconductor device and reducing the on-state resistance.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A semiconductor device, comprising:
an epitaxial layer having a first conductive type;
a gate structure disposed in the epitaxial layer and having a curved surface protruding into the epitaxial layer, wherein a breadth depth ratio of the gate structure is less than or equal to 1;
a well disposed in the epitaxial layer and having a second conductive type different from the first conductive type, wherein the well extends into the epitaxial layer along the curved surface of the gate structure and the well is in contact with the curved surface; and
a source electrode disposed above the epitaxial layer and electrically connected to the well.

2. The semiconductor device according to claim 1, further comprising a heavily doped region, wherein the well is disposed between the gate structure and the heavily doped region, the heavily doped region has a doping concentration greater than a doping concentration of the well, and a depth of the heavily doped region is greater than a depth of the well.

3. The semiconductor device according to claim 1, wherein the well does not extend to a lowest point of the curved surface, such that the well has an opening, and a width of the opening is less than 80% of a width of the gate structure.

4. The semiconductor device according to claim 2, further comprising a source region having the first conductive type and disposed between the gate structure and the heavily doped region.

5. The semiconductor device according to claim 4, wherein the well is below the source region.

6. The semiconductor device according to claim 1, wherein the curved surface of the gate structure extends upward and is connected to a top surface of the epitaxial layer.

7. The semiconductor device according to claim 1, wherein a depth of a bottom surface of the well is greater than a maximum depth of the curved surface of the gate structure.

8. The semiconductor device according to claim 7, wherein the gate structure comprises a gate electrode and a maximum depth of a curved surface of the gate electrode is less than the depth of the bottom surface of the well.

9. A method of forming a semiconductor device, comprising:
forming an epitaxial layer on a substrate, wherein the epitaxial layer has a first conductive type;
performing a first implantation process to form a well in the epitaxial layer and having a second conductive type different from the first conductive type;
performing a second implantation process to form a source region in the epitaxial layer and having the first conductive type, wherein the source region is disposed on the well;
removing a portion of the epitaxial layer, the well, and the source region to form a curved groove that is concave inward the epitaxial layer and exposes the well; and
forming a gate structure in the curved groove, wherein the gate structure has a curved surface contacting the curved groove, and a breadth depth ratio of the gate structure is less than or equal to 1.

10. The method according to claim 9, further comprising:
performing a third implantation process to form a heavily doped region in the epitaxial layer and having the second conductive type,
wherein the well is disposed between the heavily doped region and the gate structure, and a doping concentration of the heavily doped region is greater than a doping concentration of the well.

11. The method according to claim 10, wherein a depth of the heavily doped region is greater than a depth of the well.

12. The method according to claim 9, wherein the curved surface of the gate structure extends upward and is connected to a top surface of the epitaxial layer.

13. The method according to claim 9, wherein a depth of a bottom surface of the well is greater than a maximum depth of the curved surface of the gate structure.

14. The method according to claim 9, wherein the gate structure is formed in the curved groove such that the gate structure fills the curved groove and the gate structure is in contact with the well and the source region.

15. The method according to claim 9, wherein the gate structure comprises a gate electrode and a maximum depth of a curved surface of the gate electrode is less than a depth of a bottom surface of the well.
